(19) United States
(12) Patent Application Publication
(10) Pub. No.: US 2026/0201566 A1
(43) Pub. Date: Jul. 16, 2026

(54) A high-conductivity high-mobility n-type diamond thin film and preparation method thereof

(71) Applicant: ZHEJIANG UNIVERSITY OF TECHNOLOGY, Hangzhou (CN)

(72) Inventors: Xiaojun HU, Hangzhou (CN); Yuhao ZHENG, Hangzhou (CN); Binjie TANG, Hangzhou (CN); Chengke CHEN, Hangzhou (CN); Meiyan JIANG, Hangzhou (CN); Xiao LI, Hangzhou (CN); Shaohua LU, Hangzhou (CN)

(21) Appl. No.: 19/135,195

(22) PCT Filed: Dec. 15, 2023
(86) PCT No.: PCT/CN2023/139133

§ 371 Date: Jun. 3, 2025

(30) Foreign Application Priority Data
Dec. 5, 2022 (CN) 202211550172.7

(51) Int. Cl. C23C 28/04; C23C 16/27; C23C 16/56; C23C 24/08

(52) U.S. Cl. CPC C23C 28/04; C23C 16/271; C23C 16/56; C23C 24/082

(57) ABSTRACT

Disclosed in the present invention are a high-conductivity high-mobility n-type diamond thin film and a preparation method therefor. According to the method, tantalum atoms entering a thin film in a chemical vapor deposition process are doped at a nanoscale interface. The doping method is different from conventional lattice substitution doping, well solves the problem of n-type doping in diamond, and further provides a new way to solve the doping problems of other wide-band gap materials.

### TECHNICAL FIELD

The present invention relates to a high-conductivity and high-mobility N-type densely packed nano-diamond film and a preparation method thereof.

### BACKGROUND OF THE INVENTION

Diamond possesses numerous excellent physical properties, including a wide bandgap, high carrier mobility, and high thermal conductivity, making it highly valuable for electronic devices, particularly those operating under high temperature and harsh environments. However, the preparation of n-type conductive diamond remains extremely challenging, significantly hindering the realization of high-performance pn junctions. Building on the conventional lattice substitution doping theory of single-crystal silicon, researchers have investigated single-crystal or polycrystalline diamonds doped with various dopants, including nitrogen, sulfur, and phosphorus, nevertheless, the obtained n-type conductivity still fails to meet device development requirements. This indicates the necessity of exploring alternative doping methods and dopants for wide-bandgap materials like diamond, or even developing doping theories distinct from the single-crystal silicon system to address this issue.

Compared to single-crystal and microcrystalline diamond, nanocrystalline diamond exhibits unique advantages in n-type doping due to its small size effect and surface effect. However, traditional nanocrystalline diamond films contain substantial amounts of amorphous carbon or nano-graphite, which degrade film conductivity. We developed a new nanostructured diamond film in CN 201810245815.4, where nanoscale diamond particles are densely packed without amorphous carbon or nanographite. A large number of interfaces form between the nanoscale diamond grains, known as densely packed nanocrystalline diamond films, achieving high n-type carrier mobility (typically 100-300 cm²V⁻¹s⁻¹). In patent CN 201810247215.1, we further enhanced the carrier mobility (typically exceeding 400 cm²V⁻¹s⁻¹) by doping the densely packed nanocrystalline diamond film with sulfur or oxygen ions. Although the densely packed nanocrystalline diamond thin films after ion implantation show good electrical conductivity and mobility, the bombardment of high energy impurity ions causes damage to the crystal structure of diamond. Additionally, the complexity of implantation equipment complicates the corresponding processes. Furthermore, while the grains in the densely packed nanocrystalline diamond film form interconnected interfaces, misorientation between grains leads to large-angle grain boundary scattering, which reduces carrier mobility.

### BRIEF SUMMARY OF THE INVENTION

In response to these issues, the present invention subjects the prepared densely packed nanocrystalline diamond thin film to high-temperature annealing to optimize grain orientation, forming structurally ordered interfaces such as twin boundaries and stacking faults between different grains; tantalum atoms incorporated into the film during chemical vapor deposition are driven by annealing to dope the interface regions, providing high conductivity and a carrier mobility of up to 959 cm²V⁻¹s⁻¹. Notably, tantalum atoms are doped not into lattice substitution sites but into the nano-scale interface regions of the densely packed nanocrystalline diamond film, which we term “nano-interface doping.” This doping method differs from conventional lattice substitution doping, effectively resolving the challenges of n-type doping in diamond and offering a new avenue for addressing doping difficulties in other wide-bandgap materials.

The technical solutions adopted in the present invention are as follows:

The present invention provides a high-conductivity high-mobility n-type diamond thin film prepared by the following method:
(1) preparing a spin-coating solution: uniformly dispersing diamond powder with particle size of 3 nm-1 μm (preferably 3-50 nm), an adhesive, and an activator in an organic solvent to obtain a spin-coating solution; wherein the mass ratio of diamond powder to the activator is 100:5-10 (preferably 100:6); the volume of the organic solvent is 0.3-0.5 mL/mg (preferably 0.35-0.4 mL/mg, especially preferably 0.38 mL/mg) based on the mass of the diamond powder; the volume ratio of the adhesive to the organic solvent is 1:20-40 (preferably 1:38); and the activator is selected from one or more of cetyltrimethylammonium bromide, poly(diallyldimethylammonium chloride), glycerol epoxypropane, and octadecyldimethylbenzylammonium chloride;
(2) spin-coating for seed crystal deposition: applying the spin-coating solution from step (1) onto a single-crystal silicon wafer surface through spin-coating involving 15-20 cycles (preferably 20 cycles), each cycle consisting of 1000 rpm for 10 s followed by 3000 rpm for 30 s; to obtain a silicon wafer coated with a dense seed crystal layer;
(3) heat-treating: subjecting the silicon wafer coated with a dense seed layer from step (2) to heat-treatment in a tube furnace at 500-800° C. for 80-20 min (preferably 700° C. for 10 min) under an argon-protected atmosphere, yielding a heat-treated silicon wafer;
(4) using the heat-treated silicon wafer from step (3) as a substrate, performing hot-filament chemical vapor deposition with acetone as the carbon source and a tantalum wire as both the heat source and doping source to obtain a densely packed nanocrystalline diamond film;
(5) annealing the densely packed nanocrystalline diamond film from step (4) at 900-1000° C. for 30 min to obtain the high-conductivity high-mobility n-type diamond thin film.

Furthermore, in step (1), the diamond powder is typically nanodiamond powder, specifically W3 nanodiamond powder (120,000 mesh, ~36 nm particle size, prepared by a crushing method) in the embodiments of the present invention.

Furthermore, to facilitate dispersion and prevent agglomeration, the adhesive and activator in step (1) are pre-dispersed in the organic solvent before mixing.

Furthermore, in step (1), the adhesive is selected from one or more of polyvinyl alcohol, epoxy resin, and polyvinyl acetate. In an embodiment of the present invention, epoxy resin is used.

Furthermore, in step (1), the activator is cetyltrimethylammonium bromide. The selected activator satisfies two requirements required by the technical solutions: 1) the activator molecules can be adsorbed on the surface of diamond particles, creating repulsion between particles with the same polarity caused by the same terminal groups, thereby achieving the goal of preventing agglomeration of nanodiamond particles, and 2) the activator has poor thermal stability for decomposition/volatilization during subsequent heat treatment.

Furthermore, in step (1), the organic solvent is selected from one or more of dimethyl sulfoxide, acetone, and ethyl lactate. In an embodiment of the present invention, acetone is used. The selected solvent meets three requirements required by the technical scheme at the same time: 1) it has good compatibility with the activator and adhesive, 2) it can guarantee the activity of the activator, and 3) finally, it can be completely removed after heat treatment.

Furthermore, in step (2), the monocrystalline silicon wafer undergoes the following pretreatment prior to spin-coating:
it is cut into a size of 20×20 mm, placed in acetone for ultrasonic cleaning (for 10 minutes), and then dried using a nitrogen gun.

Specifically, the hot-filament chemical vapor deposition (HFCVD) described in step (4) is carried out as follows: The acetone is introduced into the reaction chamber of the HFCVD equipment by hydrogen bubbling at a flow rate of 60-100 sccm (preferably 80 sccm), simultaneously, pure hydrogen is also introduced at a flow rate of 100-300 sccm (preferably 200 sccm), the growth power is set within the range of 1800-2400 W (preferably 2200 W), the growth pressure is controlled at 1.8-2.0 KPa (preferably 2.0 KPa), the growth duration is 45-60 minutes (preferably 60 minutes), the substrate temperature is maintained at 600-700° C. (in one embodiment of the present invention, the substrate temperature is kept at 650° C.), after the growth process is completed, the supply of the carbon source is stopped, the power is then reduced to 0 at a rate of 1 V/min in a pure hydrogen atmosphere, resulting in the formation of the densely packed nanocrystalline diamond film. The grain size of the obtained film ranges from 10-30 nm, the grains are densely packed, forming interfaces between them, and the content of amorphous carbon is minimal.

Compared with the existing technologies, the beneficial effects of the present invention are mainly manifested in the following aspects:

1. It eliminates the need for ion implantation processes. Instead, by merely annealing, the n-type conductivity and mobility of the densely packed nanocrystalline diamond film are significantly enhanced. This approach is operationally simple.

2. The transition metal element, tantalum (Ta), is doped into the interfaces, pioneering a novel method of interface doping that differs from lattice doping in single-crystal silicon. This innovation effectively addresses the challenge of n-type doping in diamond and also offers a new avenue for solving doping issues in other wide-bandgap materials.

3. The film exhibits high n-type conductivity and mobility, which holds significant scientific importance and engineering value for its application in the field of semiconductor devices.

### BRIEF DESCRIPTION OF THE DRAWINGS

FIG. 1 shows the Field Emission Scanning Electron Microscope (FESEM) image of sample W3-2.0A900 from Example 1 after vacuum annealing at 900° C., captured at 50,000× magnification.

FIG. 2 shows the High-Resolution Transmission Electron Microscope (HRTEM) image of sample W3-2.0A900 from Example 1 after vacuum annealing at 900° C., and the inset displays the corresponding Selected Area Electron Diffraction (SAED) pattern of the region.

FIG. 3 shows the Aberration-Corrected Scanning Transmission Electron Microscope (AC-STEM) image of sample W3-2.0A900 from Example 1 after vacuum annealing at 900° C., the white box is where the interface is located, and tantalum atoms are marked with red circles; SubFig.s include: (a) Low-magnification AC-STEM image of Sample A-900; (b) and (c) are bright-field and dark-field images corresponding to the selected area 1 in (a), respectively; (d) and (e) are bright-field and dark-field images corresponding to the selected area 2 in (a), respectively.

FIG. 4 shows the High-Angle Annular Dark-Field (HAADF) image of sample W3-2.0A900 from Example 1 after vacuum annealing at 900° C. and Energy-Dispersive Spectroscopy (EDS) elemental mapping images for carbon (C) and tantalum (Ta).

FIG. 5 shows the FESEM image of sample W3-2.0A1000 from Example 2 after vacuum annealing at 1000° C., captured at 50,000× magnification.

FIG. 6 shows the AC-STEM images of sample W3-2.0A1000 from Example 2 after vacuum annealing at 1000° C. SubFig.s include: (a) Low-magnification AC-STEM image of the sample; (b) and (c) are high-magnification bright-field and dark-field images of the sample, respectively, with tantalum atoms marked by red circles; (d) and (e) are enlarged views of regions 1 and 2 in (b), respectively.

FIG. 7 shows the FESEM image of sample W3-1.8A900 from Example 3 after vacuum annealing at 900° C., captured at 50,000× magnification.

FIG. 8 presents the HRTEM image of sample W3-1.8A900 from Example 3 after vacuum annealing at 900° C.

FIG. 9 illustrates the AC-STEM images of sample W3-1.8A900 from Example 3 after vacuum annealing at 900° C. The white box indicates the interface location. SubFig.s include: (a) Bright-field image of the sample; (b) Dark-field image of the sample; (c) Enlarged view of the white boxed region in (b). Tantalum atoms are marked with red circles.

### DETAILED DESCRIPTION OF THE INVENTION

### Example 1

100 mg of W3 diamond powder (120000 mesh, with a particle size of approximately 36 nm) was mixed with an adhesive: 1 ml of epoxy resin (purchased from Shanghai Macklin Biochemical Co., Ltd., with the catalog number E871957)+9 ml of acetone, as well as an activator: 6 mg of cetyltrimethylammonium bromide+9 ml of acetone, all dissolved in 20 ml of acetone. The solution was then subjected to ultrasonic oscillation treatment for 60 minutes to form a suspension, which was reserved as the spin-coating solution for later use. A single-crystal silicon wafer was cut into a size of approximately 20×20 mm using a diamond knife and placed in acetone for ultrasonic cleaning for 10 minutes. After cleaning, it was blown dry with a nitrogen gun. The silicon wafer was then placed on a spin coater (purchased from Beijing Saidekaisi Electronic Co., Ltd., with the model number KW-4A) for spin-coating of the spin-coating solution. The spin-coating speed was set at 1000 rpm (for 10 seconds) followed by 3000 rpm (for 30 seconds), and the spin-coating process was repeated 20 times to apply a dense seed crystal layer onto the surface of the silicon wafer.

The silicon wafer, after spin-coating for seed crystal deposition, was placed into a tube furnace and subjected to a 700° C. heat treatment under an argon atmosphere for 10 minutes to remove organic residues from the wafer surface. Subsequently, the wafer was transferred into a hot-filament chemical vapor deposition (HFCVD) apparatus (purchased from Shanghai Jiaoyou Diamond Coating Co., Ltd., with the model number JUHFCVD001). Acetone was used as the carbon source and introduced into the reaction chamber via hydrogen bubbling. The flow rate ratio of hydrogen to acetone was maintained at 200:80 sccm. The growth power was set at 2200 W, the growth pressure was controlled at 2.0 kPa, and the growth duration was 60 minutes, with the substrate temperature kept at approximately 650° C. Upon completion of the growth process, the power was gradually reduced to 0 at a rate of 1 V/min under a hydrogen atmosphere, thereby finalizing the thin film preparation.

The densely packed nanodiamond thin film prepared as described was subjected to a 30-minute vacuum annealing treatment at 900° C. Following this treatment, the high-mobility n-type densely packed nanodiamond thin film was obtained.

The annealed thin film was coated with conductive silver electrodes for electrical performance testing. The specific steps were as follows: First, the sample surface was cleaned with acetone, followed by two one-minute ultrasonic cleanings with acetone to remove non-diamond phases from the surface. Conductive silver paint (purchased from CAIG in the USA, model CW-200B, with a sheet resistance of 0.01-0.03 Ω/sq) was applied to the four corners of the thin film in a square arrangement using a capillary tube. The silver electrodes were then dried at room temperature. The tested thin film exhibited n-type conductivity, with a Hall mobility of 8.90×10² cm²V⁻¹s⁻¹, a Hall coefficient of −2.44×10² cm³/C, a carrier concentration of −2.55×10¹⁶ cm⁻³, and a resistivity of 2.74×10⁻¹ Ω·cm. Compared with the intrinsic film grown under the same pressure without annealing (which had a Hall mobility of 4.37×10² cm²V⁻¹s⁻¹, a Hall coefficient of −1.06×10³ cm³/C, a carrier concentration of −5.88×10¹⁵ cm⁻³, and a resistivity of 2.43×10⁰ Ω·cm), it was evident that both the conductivity and mobility of the annealed film were significantly improved.

The surface morphology of the silicon wafer substrate after spin-coating and the deposited thin film was observed using a field-emission scanning electron microscope (FESEM). The microstructure composition of the deposited thin film sample was examined using a high-resolution transmission electron microscope (HRTEM). The atomic-scale structural characteristics of the sample were characterized using aberration-corrected transmission electron microscopy (AC-STEM).

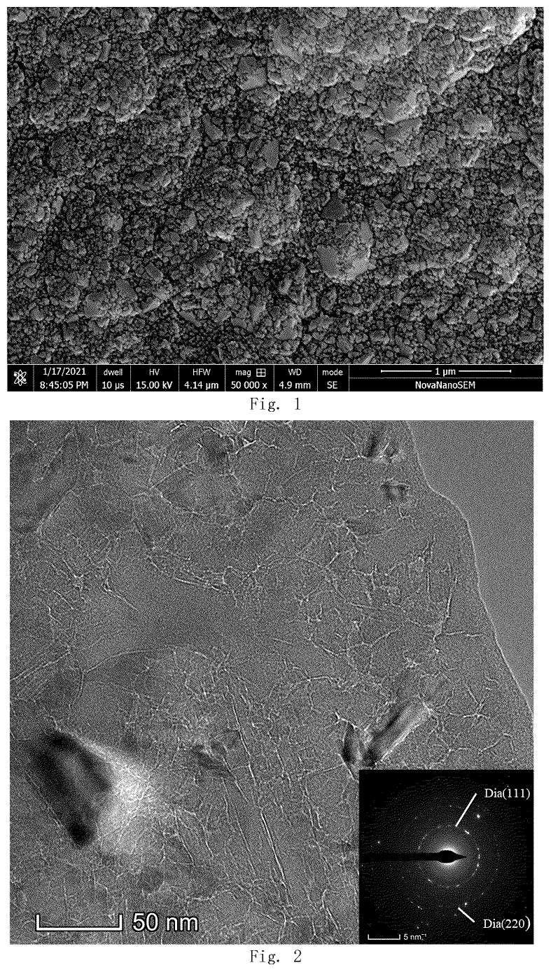

FIG. 1 shows a field-emission electron microscope image of sample W3-2.0A900 after 900° C. vacuum annealing treatment at 50,000× magnification. It can be seen that the surface consists of nanodiamond particles, forming a continuous and dense surface morphology from nanocrystals.

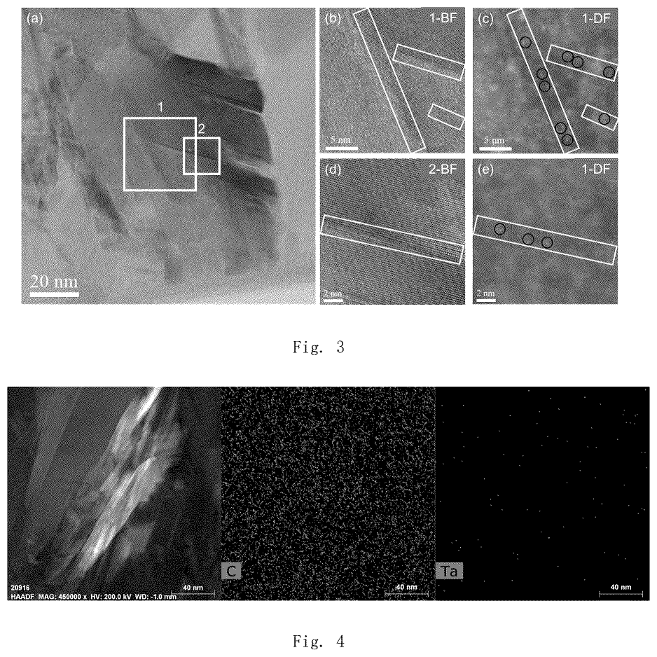

FIG. 2 presents a high-resolution transmission electron microscope image of sample W3-2.0A900 after 900° C. vacuum annealing treatment. The film exhibits a structure with slender and narrow grain boundaries enclosing irregular nanocrystals. The diamond grains are tightly packed together, showing characteristics of dense packing. From the inserted selected area electron diffraction (SAED) pattern, it can be observed that the film mainly displays the (111) and (220) crystal planes of diamond, with no diffraction information from amorphous carbon phases, indicating that the grain boundaries of the film do not contain amorphous carbon phases.

FIG. 3 presents the AC-STEM image of the sample. Similar to the observations from HRTEM characterization, we can see that the irregular grains are tightly packed together, with these interfaces corresponding to the white intersections observed in the HRTEM results. FIGS. 3(b) and 3(d) are high-magnification bright-field images of regions I and II, respectively, in FIG. 3(a), at the interfaces, there are ridges resembling mountain ridges in shape, in the corresponding dark-field images, these interfaces exhibit lower contrast, indicating that they are relatively thin, which may arise from the squeezing between different grains that causes their edges to lift up. In the corresponding dark-field images (FIGS. 3(c) and 3(e)), we can clearly observe many bright spots with high contrast, and these spots are more concentrated at the interfaces, which suggests the presence of atoms with a high atomic number in the thin film, and these atoms originate from the evaporation of tantalum (Ta) from the Ta filaments. The tantalum atoms are located at the densely packed grain interfaces, achieving interface doping.

FIG. 4 shows the High-Angle Annular Dark-Field (HADDF) image of the sample along with Energy-Dispersive X-ray Spectroscopy (EDS) elemental mapping images for carbon (C) and tantalum (Ta), confirming the presence of tantalum element.

### Example 2

100 mg of W3 diamond powder was mixed with an adhesive: 1 ml of epoxy resin+9 ml of acetone, as well as an activator: 6 mg of cetyltrimethylammonium bromide+9 ml of acetone, all dissolved in 20 ml of acetone. The solution was then subjected to ultrasonic oscillation treatment for 60 minutes to form a suspension, which was reserved as the spin-coating solution for later use. A single-crystal silicon wafer was cut into a size of approximately 20×20 mm using a diamond knife and placed in acetone for ultrasonic cleaning for 10 minutes. After cleaning, it was blown dry with a nitrogen gun. The silicon wafer was then placed on a spin coater (purchased from Beijing Saidekaisi Electronic Co., Ltd., with the model number KW-4A) for spin-coating of the spin-coating solution. The spin-coating speed was set at 1000 rpm (for 10 seconds) followed by 3000 rpm (for 30 seconds), and the spin-coating process was repeated 20 times to apply a dense seed crystal layer onto the surface of the silicon wafer.

The densely packed nanodiamond thin film prepared as described was subjected to a 30-minute vacuum annealing treatment at 1000° C. Following this treatment, the high conductivity and high mobility n-type densely packed nanodiamond thin film was obtained.

The annealed film was coated with conductive silver electrodes for electrical performance testing. The specific steps were as follows: First, the sample surface was cleaned with acetone, followed by two ultrasonic cleanings with acetone, each for one minute, to remove non-diamond phases on the surface. Conductive silver paint (purchased from CAIG, USA, model CW-200B, with a sheet resistance of 0.01-0.03 Ω/sq) was applied to the four corners of the film in a square arrangement using a capillary tube, and the silver electrodes were then dried at room temperature. The tested film exhibited n-type conductivity, with a Hall mobility of 9.59×10² cm²V⁻¹s⁻¹, a Hall coefficient of −1.37×10² cm³/C, a carrier concentration of −4.54×10¹⁶ cm⁻³, and a resistivity of 1.43×10⁻¹ Ω·cm. Compared with the unannealed intrinsic film grown under the same pressure (with a Hall mobility of 4.37×10² cm²V⁻¹s⁻¹, a Hall coefficient of −1.06×10³ cm³/C, a carrier concentration of −5.88×10¹⁵ cm⁻³, and a resistivity of 2.43×10⁰ Ω·cm), it was evident that both conductivity and mobility were significantly improved.

The surface morphology of the sample was observed using a field-emission scanning electron microscope (FESEM), and the atomic-level structural characteristics of the sample were characterized using an aberration-corrected scanning transmission electron microscope (AC-STEM).

FIG. 5 shows an FESEM image of sample W3-2.0A1000 after 1000° C. vacuum annealing at 50,000× magnification. It can be seen that the surface consists of nanodiamond particles, forming a continuous and dense surface morphology from nanocrystals.

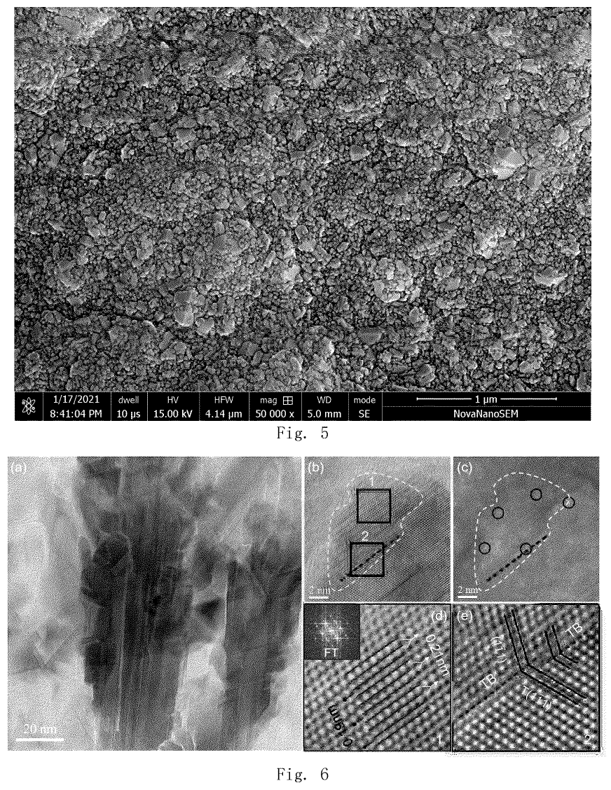

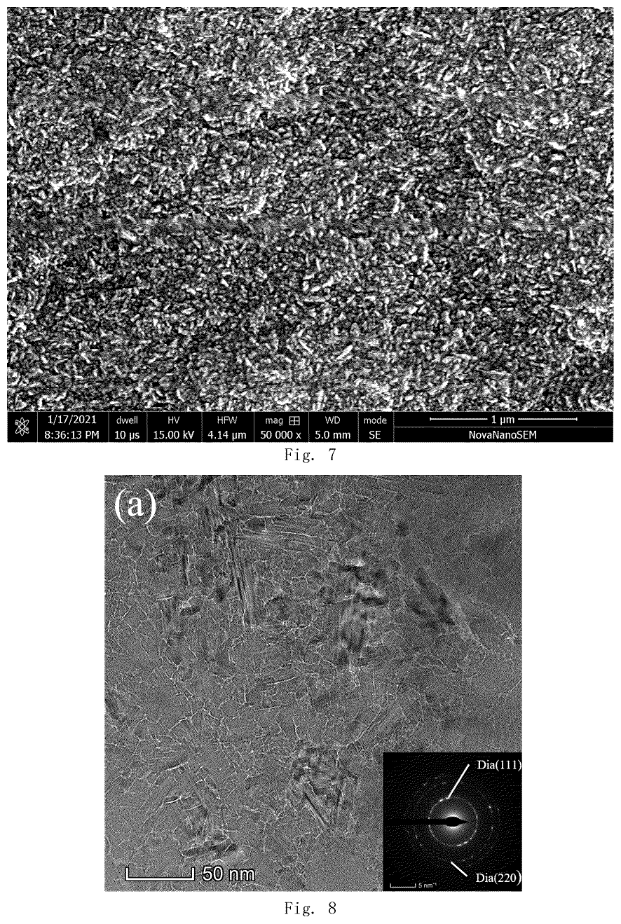

FIG. 6 shows the AC-STEM image of sample W3-2.0A1000 after 1000° C. vacuum annealing. (a) is a low-magnification AC-STEM image of sample W3-2.0A1000, showing high-density ridge-like interfaces in the film. (b) and (c) are high-magnification bright-field and dark-field images of the film, respectively. (b) shows the presence of numerous planar defects, and corresponding dark-field images reveal the presence of a large number of Ta atoms (circled in red). The detailed structures of regions 1 and 2 are shown in (d) and (e). In region 1 (orange frame, (d)), there are numerous stacking faults with an interplanar spacing of 0.19 nm, evenly spaced between every two layers. The FFT pattern shows diffraction spots parallel to the diamond (111) plane but not part of it, indicating the formation of stacking faults along the diamond (111) plane. These stacking faults cover the entire white dashed box in (b), and Ta atoms (circled in red) are found at corresponding positions in the dark-field image (c), revealing that Ta atoms are located at the stacking faults. Twin defects are shown in region 2 (green frame, (e)), where Ta atoms are also observed at the twin boundary in the dark-field image. This indicates that in the 1000° C. annealed sample, Ta atoms tend to occupy positions near planar defects, such as twin boundaries and stacking faults, achieving interface doping.

### Example 3

100 mg of W3 diamond powder was mixed with a adhesive (1 ml of epoxy resin+9 ml of acetone) and an activator (6 mg of cetyltrimethylammonium bromide+9 ml of acetone) and dissolved in 20 ml of acetone. The solution was sonicated for 60 minutes to form a suspension, which was reserved as the spin-coating solution. A single-crystal silicon wafer was cut into a size of approximately 20×20 mm using a diamond knife and placed in acetone for ultrasonic cleaning for 10 minutes. After cleaning, it was dried with a nitrogen gun. The silicon wafer was placed on a spin-coater (purchased from Beijing Saidekaisi Electronic Co., Ltd., model KW-4A) for spin-coating at 1000 rpm (10 s)+3000 rpm (30 s) for 20 times to form a dense seed layer on the surface.

The silicon wafer with the spin-coated seed layer was placed in a tube furnace for heat treatment at 700° C. under an argon atmosphere for 10 minutes to remove organic matter on the surface. Then, the silicon wafer was placed in a hot-filament chemical vapor deposition (HFCVD) device (purchased from Shanghai Jiaoyou Diamond Coating Co., Ltd., model JUHFCVD001). Acetone was used as the carbon source and introduced into the reaction chamber through hydrogen bubbling. The flow ratio of hydrogen to acetone was 200:80 sccm, the growth power was 2200 W, the growth pressure was controlled at 2.0 kPa, the growth time was 60 minutes, and the substrate temperature was maintained at approximately 650° C. After growth, the power was slowly reduced to 0 at a rate of 1 V/min in a hydrogen atmosphere to complete the film preparation process.

The prepared densely packed nanodiamond film was subjected to a 30-minute vacuum annealing treatment at 1000° C. to obtain the high-conductivity and high-mobility n-type densely packed nanodiamond film.

The annealed film is coated with conductive silver electrodes for electrical performance testing. The specific steps are as follows: First, the sample surface is cleaned with acetone, followed by ultrasonic cleaning of the sample with acetone twice, for one minute each time, to remove the non-diamond phases on the surface. A capillary tube is used to apply four conductive silver paint dots (purchased from CAIG, USA, model CW-200B, with a sheet resistance of 0.01-0.03 Ω/sq) at the four corners of the film, arranged in a square pattern. Subsequently, the silver electrodes are dried at room temperature. The tested film exhibits n-type conductivity, with a Hall mobility of 5.42×10² cm²V⁻¹s⁻¹, a Hall coefficient of −1.15×10² cm³/C, a carrier concentration of 5.42×10¹⁶ cm⁻³, and a resistivity of 2.12×10⁻¹ Ω·cm. Compared with the unannealed intrinsic film grown under the same pressure (with a Hall mobility of 1.81×10¹ cm²V⁻¹s⁻¹, a Hall coefficient of −4.22×10⁰ cm³/C, a carrier concentration of −1.48×10¹⁸ cm⁻³, and a resistivity of 2.33×10⁻¹ Ω·cm), it can be seen that the electrical conductivity of the annealed film is slightly improved, while the mobility is significantly enhanced.

A field-emission scanning electron microscope (FESEM) is used to observe the surface morphology of the film after vacuum annealing treatment at 900° C. A high-resolution transmission electron microscope (HRTEM) is employed to observe the microstructural composition of the deposited film samples. A spherical aberration-corrected transmission electron microscope (AC-STEM) is utilized to characterize the atomic-level structural features of the samples.

FIG. 7 shows a field-emission scanning electron microscope (FESEM) image of sample W3-1.8A1000 after vacuum annealing treatment at 900° C., taken at 50,000× magnification. It can be observed that the surface consists of nanodiamond particles, forming a continuous and dense surface morphology composed of needle-like nanocrystals.

FIG. 8 presents a high-resolution transmission electron microscope (HRTEM) image of sample W3-1.8A900 after vacuum annealing treatment at 900° C. The film exhibits a structure of slender and narrow grain boundaries enclosing irregular nanocrystals. The diamond grains are tightly packed together, showing a densely packed characteristic. From the inserted selected area electron diffraction (SAED) pattern, it can be seen that the (111) and (220) crystal planes of diamond are dominant, and there is no diffraction information of amorphous carbon phases, indicating an extremely low content of amorphous carbon in the film grain boundaries, which is a typical densely packed grain structure.

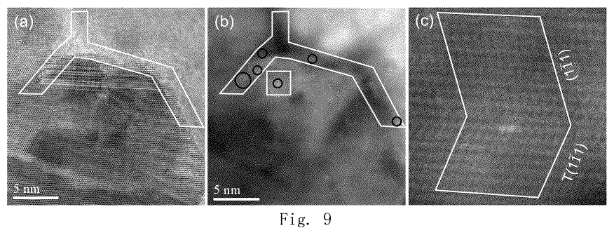

FIG. 9(a) is a high-magnification bright-field spherical aberration-corrected transmission electron microscope (SACTEM) image of sample W3-1.8A900 after vacuum annealing treatment at 900° C. The high-magnification bright-field SACTEM image in FIG. 9(a) shows an interplanar spacing of 0.206 nm, corresponding to the (111) plane of diamond. The white box indicates the interface of the closely packed grains. From the dark-field image (b), it can be observed that there are many bright spots with high contrast at the interface, which, similar to Example 1, are tantalum impurities present during the hot-filament vapor-phase growth process. Fig. (c) is an enlarged view of the white box in (b), clearly showing that tantalum atoms are located at the (111) twin boundaries of diamond. The tantalum atoms are located at the densely packed grain interfaces, achieving interface doping.

### Example 4

100 mg of W3 diamond powder (120,000 mesh, with a particle size of approximately 36 nm) was mixed with an adhesive consisting of 1 ml of epoxy resin (purchased from Shanghai Macklin Biochemical Co., Ltd., product number E871957)+9 ml of acetone, and an activator consisting of 6 mg of cetyltrimethylammonium bromide+9 ml of acetone. All components were dissolved together in 20 ml of acetone. The solution was then subjected to ultrasonic agitation for 60 minutes to form a suspension, which was reserved as the spin-coating solution for later use. A single-crystal silicon wafer was cut into approximately 20×20 mm pieces using a diamond knife and ultrasonically cleaned in acetone for 10 minutes. After cleaning, the wafer was dried with a nitrogen gun. The silicon wafer was placed on a spin coater (purchased from Beijing Saidekaisi Electronic Co., Ltd., model KW-4A) and coated with the seed crystal spin-coating solution. The spin-coating speeds were 1000 rpm (for 10 seconds) followed by 3000 rpm (for 30 seconds), and the spin-coating process was repeated 20 times to form a dense seed crystal layer on the surface of the silicon wafer.

The silicon wafer coated with seed crystals was placed in a tube furnace and subjected to a heat treatment at 700° C. under an argon atmosphere for 10 minutes to remove organic matter from the surface of the wafer. Subsequently, the wafer was placed in a hot-filament chemical vapor deposition (HFCVD) equipment (purchased from Shanghai Jiaoyou Diamond Coating Co., Ltd., model JUHFCVD001). Acetone was used as the carbon source and introduced into the reaction chamber by hydrogen bubbling. The flow rate ratio of hydrogen to acetone was 200:80 sccm, the growth power was 2200 W, the growth pressure was controlled at 2.0 kPa, and the growth time was 60 minutes, with the substrate temperature maintained at approximately 650° C. After the growth was completed, the power was gradually reduced to 0 at a rate of 1 V/min in a hydrogen atmosphere to complete the film preparation process.

The prepared closely packed nanodiamond film was subjected to a vacuum annealing treatment at 800° C. for 30 minutes. The annealed film was then coated with conductive silver electrodes for electrical performance testing. The specific steps were as follows: First, the sample surface was cleaned with acetone, followed by ultrasonic cleaning of the sample with acetone twice, for one minute each time, to remove the non-diamond phases on the surface. A capillary tube was used to apply four conductive silver paint dots (purchased from CAIG, USA, model CW-200B, with a sheet resistance of 0.01-0.03 Ω/sq) at the four corners of the film, arranged in a square pattern. The silver electrodes were then dried at room temperature. The tested film exhibited n-type conductivity, with a Hall mobility of 94.5 cm²V⁻¹s⁻¹, a Hall coefficient of −2.44×10² cm³/C, a carrier concentration of −1.80×10¹⁶ cm⁻³, and a resistivity of 3.66 Ω·cm. Compared with the unannealed intrinsic film grown under the same pressure (with a Hall mobility of 4.37×10² cm²V⁻¹s⁻¹, a Hall coefficient of −1.06×10³ cm³/C, a carrier concentration of −5.88×10¹⁵ cm⁻³, and a resistivity of 2.43×10⁰ Ω·cm), it can be seen that both the electrical conductivity and mobility of the annealed film decreased to a certain extent. This demonstrates that the 800° C. vacuum annealing treatment cannot produce the n-type closely packed nanodiamond film with high electrical conductivity and high mobility obtained in the aforementioned cases.

1. A high-conductivity high-mobility n-type diamond thin film, characterized in that the high conductivity high mobility n-type diamond thin film is prepared by the following method:
(1) preparing a spin-coating solution: uniformly dispersing diamond powder with particle size of 3 nm-1 μm, an adhesive, and an activator in an organic solvent to obtain a spin-coating solution; wherein the mass ratio of diamond powder to the activator is 100:5-10; the volume of the organic solvent is 0.3-0.5 mL/mg based on the mass of the diamond powder; the volume ratio of the adhesive to the organic solvent is 1:20-40; and the activator is selected from one or more of cetyltrimethylammonium bromide, poly(diallyldimethylammonium chloride), glycerol epoxypropane, and octadecyldimethylbenzylammonium chloride;
(2) spin-coating for seed crystal deposition: applying the spin-coating solution from step (1) onto a single-crystal silicon wafer surface through spin-coating involving 15-20 cycles, each cycle consisting of 1000 rpm for 10 s followed by 3000 rpm for 30 s; to obtain a silicon wafer coated with a dense seed crystal layer;
(3) heat-treating: subjecting the silicon wafer coated with a dense seed layer from step (2) to heat-treatment in a tube furnace at 500-800° C. for 80-20 min under an argon-protected atmosphere, yielding a heat-treated silicon wafer;
(4) using the heat-treated silicon wafer from step (3) as a substrate, performing hot-filament chemical vapor deposition with acetone as the carbon source and a tantalum wire as both the heat source and doping source to obtain a densely packed nanocrystalline diamond film;
(5) annealing the densely packed nanocrystalline diamond film from step (4) at 900-1000° C. for 30 min to obtain the high-conductivity high-mobility n-type diamond thin film.

2. The high conductivity high mobility n-type diamond thin film according to claim 1, characterized in that: in step (1), the diamond powder is W3 nanodiamond powder.

3. The high conductivity high mobility n-type diamond thin film according to claim 1, characterized in that: in step (1), the adhesive is selected from one or more of polyvinyl alcohol, epoxy resin, and polyvinyl acetate.

4. The high conductivity high mobility n-type diamond thin film according to claim 1, characterized in that: in step (1), the adhesive is epoxy resin.

5. The high conductivity high mobility n-type diamond thin film according to claim 1, characterized in that: in step (1), the activator is cetyltrimethylammonium bromide.

6. The high conductivity high mobility n-type diamond thin film according to claim 1, characterized in that: in step (1), the organic solvent is selected from one or more of dimethyl sulfoxide, acetone, and ethyl lactate.

7. The high conductivity high mobility n-type diamond thin film according to claim 1, characterized in that: in step (1), the organic solvent is acetone.

8. The high conductivity high mobility n-type diamond thin film according to claim 1, characterized in that: in step (2), the single-crystal silicon wafer undergoes the following pretreatment prior to spin-coating:
it is cut into a size of 20×20 mm, placed in acetone for ultrasonic cleaning, and then dried using a nitrogen gun.

9. The high conductivity high mobility n-type diamond thin film according to claim 1, characterized in that: the hot-filament chemical vapor deposition described in step (4) is carried out as follows: the acetone is introduced into the reaction chamber of the HFCVD equipment by hydrogen bubbling at a flow rate of 60-100 sccm, simultaneously, pure hydrogen is also introduced at a flow rate of 100-300 sccm, the growth power is set within the range of 1800-2400 W, the growth pressure is controlled at 1.8-2.0 KPa, the growth duration is 45-60 minutes, after the growth process is completed, the supply of the carbon source is stopped, the power is then reduced to 0 at a rate of 1 V/min in a pure hydrogen atmosphere, resulting in the formation of the densely packed nanocrystalline diamond film.

10. The high conductivity high mobility n-type diamond thin film according to claim 9, characterized in that: the growth power is set at 2200 W, the growth pressure is controlled at 2.0 KPa, the growth duration is 60 minutes.
